(19) United States
(12) Patent Application Publication
(10) Pub. No.: US 2006/0249074 A1
(43) Pub. Date: Nov. 9, 2006

(54) Method for supplying hydrogen gas in silicon single-crystal growth, and method for manufacturing silicon single-crystal

(75) Inventors: Wataru Sugimura, Tokyo (JP); Masataka Hourai, Tokyo (JP)

Correspondence Address: PILLSBURY WINTHROP SHAW PITTMAN, LLP, P.O. BOX 10500, MCLEAN, VA, 22102, US

(73) Assignee: SUMCO CORPORATION, Tokyo (JP)

(21) Appl. No.: 11/122,233

(22) Filed: May 5, 2005

(51) Int. Cl. C30B 23/00; C30B 25/00; C30B 28/12; C30B 28/14

(52) U.S. Cl. 117/84

(57) ABSTRACT

This method for supplying hydrogen gas in silicon single-crystal growth is characterized by including feeding hydrogen gas at a hydrogen gas concentration of less than X₁ into a single-crystal pulling furnace during growth of a silicon single-crystal by the CZ process in a hydrogen-containing inert atmosphere, wherein the hydrogen gas concentration X₁ is defined as, in a triangular diagram of a ternary system of hydrogen gas, oxygen gas and inert gas having vertices A, B and C where K₁ is a mixed gas dilution limit for detonation and D is a composition of air on a side BC representing a volumetric ratio of the oxygen gas and the inert gas, hydrogen gas concentration at a point S₁ where a straight line from D toward K₁ intersects a side CA representing a volumetric ratio of the inert gas and the hydrogen gas.

### BACKGROUND OF THE INVENTION

1. Field of the Invention

The present invention relates to a method for supplying hydrogen gas during the growth of a hydrogen-doped silicon single-crystal.

2. Background Art

The method typically used for manufacturing a silicon single-crystal from which silicon wafers are prepared is a rotary crystal pulling technique known as the Czochralski (CZ) method. As is well known, in the manufacture of a silicon single-crystal ingot by the CZ method, a seed crystal is immersed in a silicon melt that has been formed in a quartz crucible, then is pulled upward while both the crucible and the seed crystal are rotated, thereby growing a silicon single-crystal below the seed crystal.

An inert gas (primarily argon gas) has hitherto been used as the atmosphere in a furnace in such a CZ crystal pulling process. The purpose is to inhibit various chemical reactions with the furnace members and the crystal, and thus avoid the entry of impurities that form as by-products. In addition, gas stream that arises in the furnace with a supply of a large amount of gas is used to avoid metal contamination and achieve a higher quality in the pulled crystal.

Reports have recently begun to appear on the effectiveness of mixing a trace amount of hydrogen gas in this internal furnace atmosphere (e.g., Patent References 1 to 4). The hydrogen supplied in this way acts upon grown-in defects, particularly vacancies, that have been incorporated into the crystal, enabling the vacancies to be reduced or eliminated in the same way as with the nitrogen doping of the silicon melt.

Patent Reference 1: Japanese Unexamined Patent Application, First Publication No. S61-178495

Patent Reference 2: Japanese Unexamined Patent Application, First Publication No. H11-189495

Patent Reference 3: Japanese Unexamined Patent Application, First Publication No. 2000-281491

Patent Reference 4: Japanese Patent Application, First Publication No. 2001-335396

In such hydrogen doping techniques during CZ crystal pulling, the hydrogen gas concentration in the mixed gas has hitherto been limited to a maximum of 3 vol % so as to prevent a danger of explosions. Incidentally, the lower flammability limit for hydrogen in air is 4 vol %.

However, such a limit makes for a narrow allowable concentration range during hydrogen gas mixing, which restricts the workability during operation. We have confirmed from experiments that a clear hydrogen effect cannot be achieved at a hydrogen gas concentration below 3 vol %.

### SUMMARY OF THE INVENTION

It is therefore an object of the present invention to provide a method for supplying hydrogen gas which enables the admixture of a high concentration of hydrogen gas while maintaining safety.

To achieve the above objects, we have conducted detailed investigations on the explosion hazards when a silicon single-crystal is grown by the CZ method in a hydrogen-containing inert atmosphere. As a result, we have reached the following conclusions.

Mixing hydrogen gas into an inert gas to be supplied to the crystal pulling furnace is not in itself dangerous. Even when the hydrogen gas concentration in the mixed gas reaches 50%, there is no danger of explosion so long as the mixed gas consists only of inert gas and hydrogen gas. What is dangerous is the possibility of outside air leaking into the furnace. That is, the interior of the furnace is maintained at a predetermined degree of vacuum during furnace operation. Hence, there is always a chance that outside air will leak into the furnace. If such a leak does occur, air will enter the furnace, bringing with it oxygen, which can lead to an explosion.

More specifically, if a leak of outside air into the furnace occurs, the composition of the atmosphere in the furnace gradually approaches that outside the furnace. Explosions occur in the course of this process, not the moment a leak of outside air into the furnace arises. The high initial concentration of hydrogen gas does not present an immediate risk of explosion. This is one reason why the hydrogen gas concentration can be increased.

Explosions are classified as either merely combustion or detonation which is more intense combustion. In the detonation, the gases in the furnace undergo a large and rapid expansion, whereas in combustion the degree of such expansion is at least several times smaller. According to our calculations, in the CZ crystal pulling, because the pressure in the furnace is lowered to a prescribed degree of vacuum, even if combustion does occur in the furnace, the pressure in the furnace will not exceed atmospheric pressure. Therefore, an equipment failure accident such as breaking of the crucible in the crystal pulling furnace does not arise. However, when the detonation occurs, the pressure in the furnace exceeds atmospheric pressure, leading to a major accident involving equipment failure. It is therefore essential to avoid detonation, but there is no need to avoid also any combustion. Herein lies a second reason why the hydrogen gas concentration can be increased.

The method for supplying hydrogen gas of the present invention was accomplised based on these ideas, and is characterized by feeding hydrogen gas at a hydrogen gas concentration of less than X₁ into a single-crystal pulling furnace during growth of a silicon single-crystal by the CZ process in a hydrogen-containing inert atmosphere.

Here, the hydrogen gas concentration X₁ is defined as, in a triangular diagram of a ternary system of hydrogen gas, oxygen gas and inert gas having vertices A, B and C where K₁ is a mixed gas dilution limit for detonation and D is a composition of air on a side BC representing a volumetric ratio of the oxygen gas and the inert gas, the hydrogen gas concentration at a point S₁ where a straight line from D toward K₁ intersects a side CA representing a volumetric ratio of the inert gas and the hydrogen gas.

During the silicon single-crystal growth by the CZ process in the hydrogen-containing inert atmosphere, the method for supplying hydrogen gas of the present invention controls the hydrogen gas concentration to be a limit value at which detonation can be avoided or less, thereby enabling the concentration to be made higher than in the prior art while maintaining safety. This expands the degree of freedom in furnace operation, and enables effects such as defect suppression by the admixture of hydrogen to be greatly enhanced.

In the method for supplying hydrogen gas of the present invention, letting L₁ to L₁′ be a detonation range on a side AB representing a volumetric ratio of the hydrogen gas and the oxygen gas and letting M₁ to M₁′ be a detonation range on a straight line DA which connects the air composition D on a side BC representing the volumetric ratio of the oxygen gas and inert gas with the vertex A, the mixed gas dilution limit for detonation K₁ may be expressed as a point where straight line L₁M₁ and straight line L₁′M₁′ intersect.

In the method for supplying hydrogen gas of the present invention, letting the point S₁ on the side CA be a first critical point, furnace operation is carried out in a hydrogen concentration range of less than the hydrogen gas concentration X₁ at this point S₁. More precisely, letting a point S₂ described below on side CA be a second critical point, the furnace operation is classified as an operation carried out in a hydrogen concentration range of at least the hydrogen gas concentration X₂ at this point S₂, that is, at least X₂ but less than X₁; and an operation carried out in a hydrogen concentration range below the hydrogen gas concentration X₂ at point S₂, that is, below X₂.

Here, the hydrogen gas concentration X₂ is defined as, in a triangular diagram of a ternary system of hydrogen gas, oxygen gas and inert gas having vertices A, B and C where K₂ is a mixed gas dilution limit for combustion and D is the air composition on side BC representing the volumetric ratio of the oxygen gas and the inert gas, the hydrogen gas concentration at a point S₂ where a straight line from D toward K₂ intersects side CA representing the volumetric ratio of the inert gas and the hydrogen gas.

Letting L₂ to L₂′ be a combustion range on side AB representing the volumetric ratio of the hydrogen gas and the oxygen gas and letting M₂ to M₂′ be a combustion range on a straight line DA which connects the air composition D on side BC representing the volumetric ratio of the oxygen gas and inert gas with the vertex A, the mixed gas dilution limit for combustion K₂ may be expressed as a point where straight line L₂M₂ and straight line L₂′M₂′ intersect.

As will be explained more fully below, in furnace operation at points S₁ to S₂ (exclusive of point S₁) on side CA, that is, in furnace operation using a mixed gas of hydrogen gas and inert gas having a hydrogen gas concentration of at least X₂, but less than X₁, if a leak of outside air into the furnace occurs, combustion will take place but not detonation. In furnace operation at point S₂ to point C (exclusive of point S₂), that is, in operation using a mixed gas of hydrogen gas and inert gas having a hydrogen gas concentration below X₂, if a leak of outside air into the furnace occurs, neither detonation nor combustion will take place.

In the former type of furnace operation where the operation point S (the volumetric ratio of hydrogen gas and inert gas in the mixed gas that is used) lies at point S₁ to point S₂ (exclusive of point S₁) on side CA, it is preferable for an alarm to be set off until the oxygen gas concentration O₀ described below is reached. More specifically, it is preferable for an alarm to be set off when the oxygen gas concentration in the furnace atmosphere gases reaches a value in a range from 0.1-fold to 0.25-fold of the oxygen gas concentration O₀ as described below. In this way, it is possible to detect beforehand the occurrence of unavoidable combustion in the former type of furnace operation.

Here, the oxygen gas concentration O₀ is defined as a oxygen gas concentration at a point S₀ where a straight line DS that connects the air composition D on the side BC representing the volumetric ratio of the oxygen gas and the inert gas with an operation point S on the side CA representing the volumetric ratio of the inert gas and the hydrogen gas intersects a straight line L₂′K₂ representing the upper limit of a combustion region.

The lower limit of the hydrogen gas concentration is not subject to any particular limitation, provided it is more than 0. However, to increase the hydrogen mixing effect, it is preferably more than 3 vol %, and most preferably 5% or more. It should be noted that the hydrogen gas concentration X₂ at point S₂ is 10%.

The method for manufacturing a silicon single-crystal of the present invention is characterized by including a step of growing a silicon single-crystal by the CZ method in an hydrogen-containing inert atmosphere and a step of feeding hydrogen gas into the single-crystal pulling furnace at a hydrogen gas concentration of less than X₁, wherein the hydrogen gas concentration X₁ is defined as, in a triangular diagram of a ternary system of hydrogen gas, oxygen gas and inert gas having vertices A, B and C where K₁ is a mixed gas dilution limit for detonation and D is a composition of air on side BC representing a volumetric ratio of the oxygen gas and the inert gas, the hydrogen gas concentration at a point S₁ where a straight line from D toward K₁ intersects side CA representing a volumetric ratio of the inert gas and the hydrogen gas.

### BRIEF DESCRIPTION OF THE DRAWINGS

FIG. 1 is a schematic diagram showing the construction of a CZ crystal-pulling furnace.

FIG. 2 is a triangular diagram of a ternary system of hydrogen gas, oxygen gas and inert gas having vertices A, B and C.

### PREFERRED EMBODIMENTS

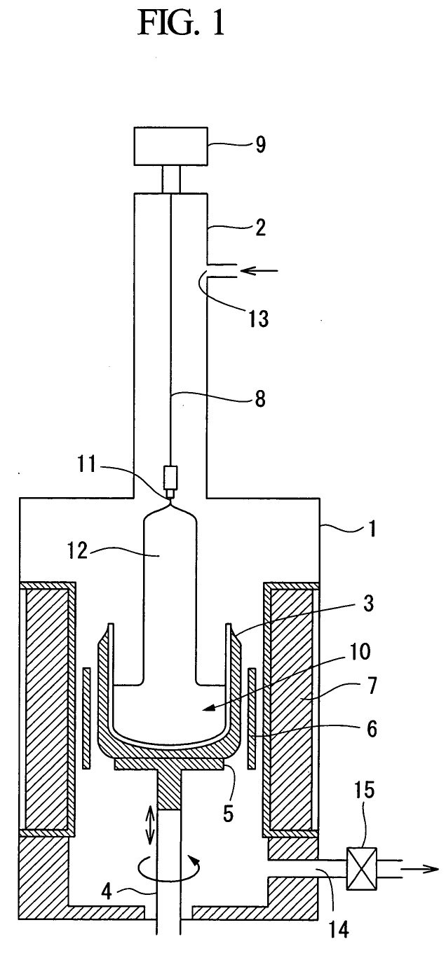

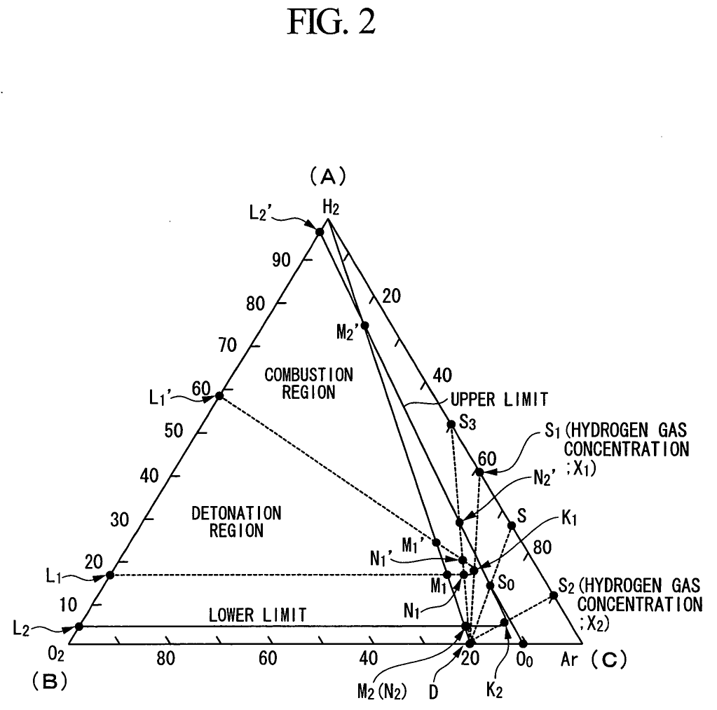

Embodiments of the invention are described below in conjunction with the attached diagrams. FIG. 1 is a schematic diagram showing the construction of a CZ crystal-pulling furnace, and FIG. 2 is a triangular diagram of a ternary system of hydrogen gas, oxygen gas and inert gas having vertices A, B and C.

Referring to FIG. 1, a CZ crystal pulling furnace has a furnace body having a cylindrical main chamber 1 and a small-diameter pull chamber 2 stacked on top thereof.

A crucible 3 is disposed in the main chamber 1 at a central position. The crucible 3 has a double construction composed of a graphite crucible on the outside which holds a quartz crucible on the inside, and is supported on a shaft 4 called a pedestal through an intervening crucible support 5. The support shaft 4 is driven in the axial and circumferential directions by a drive mechanism disposed below the main chamber 1 for raising, lowering, and rotating the crucible 3.

A ring-like heater 6 is disposed outside of the crucible 3, and thermal insulation 7 is disposed outside of the heater 6 along an inner wall of the main chamber 1.

A wire 8 is suspended as a crystal pulling axis in a pull chamber 2 over the main chamber 1, and reaches into the main chamber 1. The wire 8 is raised upward and rotated by a drive mechanism 9 provided above the pull chamber 2.

In furnace operation, first a melt 10 of a silicon starting material is formed in the crucible 3. A seed crystal 11 mounted at the bottom end of the wire 8 is immersed in the melt 10, then the wire 8 is raised upward while the crucible 3 and the wire 8 are rotated, thereby growing a silicon single-crystal 12 downward from the seed crystal 11.

At this time, a pressure in the furnace is lowered to a prescribed degree of vacuum and, in this state, a mixed gas of argon as an inert gas and hydrogen is circulated down through the furnace. To enable such gas circulation, a gas inlet 13 is provided at the top of the pull chamber 2 and a gas outlet 14 connected to a vacuum discharge pump is provided at the bottom of the main chamber 1.

An oxygen sensor 15 which measures the oxygen concentration in the discharged gas is provided in a gas discharge line coupled to the gas outlet 14. Also provided is a system (not shown) which, based on this measured oxygen concentration, recognizes the oxygen gas concentration in the ambient gas in the furnace and sets off an alarm depending on the measured oxygen concentration.

In this embodiment, the composition of the mixed gas fed to the furnace interior, i.e., the hydrogen gas concentration, is important. The hydrogen gas can first be mixed with the inert gas outside of the furnace then fed into the furnace, or can instead be independently fed into the furnace by a separate route and mixed with the inert gas inside the furnace.

The method for setting the hydrogen gas concentration in the furnace atmosphere is explained in detail below using the triangular diagram shown in FIG. 2. In the following explanation, unless noted otherwise, percent (%) refers to percent by volume (vol %).

The triangular graph shown in FIG. 2 depicts a ternary system of hydrogen gas, oxygen gas and inert gas, and has the vertices A, B and C. The inert gas is argon gas which is commonly used in CZ crystal pulling, although the inert gas nitrogen in air or helium gas may be used in place of argon.

The vertices A, B and C represent pure components; that is, 100% hydrogen gas, 100% oxygen gas and 100% inert gas, respectively. The side AB represents the compositional ratio in a mixture of hydrogen gas and oxygen gas, with the numbers indicating the hydrogen gas concentration in this mixture. Likewise, side BC represents the compositional ratio in a mixture of oxygen gas and argon gas, with the numbers indicating the oxygen gas concentration in this mixture. Side CA represents the compositional ratio in a mixture of argon gas and hydrogen gas, with the numbers representing the argon gas concentration in this mixture.

The composition of air, which is basically a mixture of oxygen gas and nitrogen gas (inert gas), is represented by point D on side BC. The straight line DA represents the compositional ratio in a mixture of air and hydrogen gas. Mixing hydrogen gas into air progressively lowers the combined content of the oxygen gas and nitrogen gas (inert gas) while maintaining the relative mixing ratio therebetween, to a point where the mixture ultimately becomes pure hydrogen gas.

On the side AB representing the compositional ratio in a mixture of hydrogen gas and oxygen gas, if the hydrogen gas concentration is gradually increased from 0% (pure oxygen gas), L₂ to L₂′ is the combustion range and, within this, L₁ to L₁′ in particular is the detonation range. These hydrogen concentration limit values are known: the hydrogen concentration at the lower limit of combustion L₂ is 4%; the hydrogen concentration at the upper limit of combustion L₂′ is 95.8%; the hydrogen concentration at the lower limit L₁ of detonation is 18.3%; and the hydrogen concentration at the upper limit of detonation L₁′ is 59%.

Similarly, on the straight line DA representing the compositional ratio in a mixture of air and hydrogen gas, if the hydrogen gas concentration is gradually increased from 0% (air only), M₂ to M₂′ is the combustion range and, within this, M₁ to M₁′ in particular is the detonation range. These hydrogen concentration limit values, which can be accurately determined by experimentation, are as follows: the hydrogen concentration at the lower limit of combustion M₂ is 4%, the hydrogen concentration at the upper limit of combustion M₂′ is 75%, the hydrogen concentration at the lower limit M₁ of detonation is 18.3%, and the hydrogen concentration at the upper limit of detonation M₁′ is 27%.

Straight line L₂M₂ and straight line L₂′M₂′ intersect at projections therefrom, the point of intersection K₂ being a dilution limit for combustion of the mixed gas in the ternary system. Likewise, straight line L₁M₁ and straight line L₁′M₁′ intersect at projections therefrom, the point of intersection K₁ being the dilution limit for detonation of the mixed gas in the ternary system. The interior of the triangle L₂K₂L₂′ is the combustion region in this ternary mixed gas system, and the interior of the triangle L₁K₁L₁′ formed therein is the detonation region in the ternary mixed gas system.

Side CA representing the compositional ratio in a mixture of argon gas and hydrogen gas corresponds to the compositional ratio of the mixed gas of argon and hydrogen fed to the CZ crystal pulling furnace. Because this side CA enters neither the detonation region represented by the triangle L₁K₁L₁′ nor the combustion region represented by the triangle L₂K₂L₂′, there is no danger of explosion by the mixed gas of argon and hydrogen itself. However, if air enters the low-pressure furnace due to the leakage of outside air, a danger of explosion will arise depending on the hydrogen gas concentration in the mixed gas.

Specifically, if outside air leaks into the crystal pulling furnace when the hydrogen gas concentration in the mixed gas of argon and hydrogen filling the furnace is 50% (operation point S₃), the furnace atmosphere moves on straight line S₃D from S₃ toward D. Along the way, the furnace atmosphere enters the combustion region at N₂′, and enters the detonation region at N₁′. As the leak proceeds further and the atmosphere in the furnace approaches the composition of air, the furnace atmosphere leaves the detonation region at N₁ and leaves the combustion region at N₂. That is, when the furnace atmosphere is a mixed gas that is 50% hydrogen, detonation from the leakage of outside air into the furnace cannot be avoided.

Letting the point where the straight line from the outside air composition D on side BC to the dilution limit K₁ for detonation of the ternary mixed gas intersects side CA be S₁, and assuming that a leak of outside air has occurred when the hydrogen gas concentration in the mixed gas of argon and hydrogen filling the interior of the crystal pulling furnace is the hydrogen gas concentration X₁ at this point S₁, the furnace atmosphere moves on straight line S₁D from S₁ to D. This time, the furnace atmosphere passes through the combustion region, but merely glances by the detonation region at the dilution limit K₁. Therefore, so long as the hydrogen gas concentration in the mixed gas in the furnace is less than the hydrogen gas concentration X₁ at this point S₁, even if a leak of outside air does occur, it will not lead to a detonation.

The hydrogen gas concentration X₁ at this intersection S₁ has an upper limit of at least 30%, which is far higher than the concentration of 3% that has been considered in the prior art.

Hence, the method for supplying hydrogen gas of the present invention enables the admixture of high concentrations of hydrogen gas exceeding 3% while avoiding detonations that present a danger of equipment failure. In this way, the degree of freedom in furnace operation is increased while making it possible to take full advantage of the desirable effects of hydrogen admixture, including defect suppression.

In addition, letting the point where the straight line from the outside air composition D on side BC to the dilution limit K₂ for combustion of the ternary mixed gas intersects side CA be S₂, if the hydrogen gas concentration in the mixed gas in the furnace is less than the hydrogen gas concentration X₂ at this point S₂, even combustion can be prevented. It should be noted that the upper limit in the hydrogen gas concentration X₂ represented by the intersection S₂ is 10%.

When the hydrogen gas concentration is in a range from at least X₂ to less than X₁, even if outside air should leak into the furnace, the danger of such an accident can be limited to combustion only. As noted above, in the case of combustion, the pressure inside the furnace does not exceed atmospheric pressure, so there is no danger of equipment failure such as crucible breakage.

Here, the case in which furnace operation is carried out at an S point where the hydrogen gas concentration is in a range from at least X₂ to less than X₁ is described in greater detail. When a leak of outside air occurs during such operation, the atmosphere in the furnace moves on straight line SD from the S point to the D point, in the course of which it enters the combustion region at a point S₀. Letting O₀ be the point where a straight line that is parallel to straight line CA and passes through point S₀ intersects straight line BC, the point O₀ represents the oxygen concentration at point S₀. That is, if a leak of outside air occurs during furnace operation, the oxygen gas concentration in the ambient gases in the furnace moves on side BC from point C in a direction toward point B, entering the combustion region at point O₀ along the way. Hence, if the oxygen concentration in the ambient gases during operation is measured and a rise in the measured oxygen concentration is sensed, a leak in outside air can be detected. By causing an alarm to be set off before the measured oxygen concentration reaches the oxygen concentration represented by point O₀, the leak of outside air can be detected before combustion begins.

In such a case, it is important in actual operation to factor in such considerations as the response time when a leak of outside air occurs. From this standpoint, it is desirable in actual operation for an alarm to be set off when an oxygen concentration equal to a value obtained by multiplying the oxygen concentration represented by point O₀ and a safety factor of 0.1 to 0.25 together is detected. In the case in which the safety factor is less than 0.1, the sensitivity is too high, which may result in false detection. On the other hand, at the safety factor of more than 0.25, the response time for an outside air leak is insufficient, and malfunction due to measurement errors by the oxygen sensor becomes a problem.

For the sake of convenience, the triangular diagram shown in FIG. 2 represents a system at standard temperature and atmospheric pressure. However, combustion and detonation tend to be suppressed in a furnace operated under reduced pressure. Hence, if it is possible to avoid detonation and combustion in the triangular diagram shown in FIG. 2, then detonation and combustion can be avoided during actual operation even in a high-temperature atmosphere in the furnace. Needless to say, use may be made of a triangular diagram which takes into consideration the operating conditions in the furnace.

Some preferred embodiments of the invention have been described above, although these embodiments are to be considered in all respects as illustrative and not limitative. Those skilled in the art will appreciate that various additions, omissions, substitutions and other modifications are possible without departing from the spirit and scope of the invention as disclosed in the accompanying claims.

What is claimed is:

1. A method for supplying hydrogen gas in silicon single-crystal growth, the method comprising feeding hydrogen gas at a hydrogen gas concentration of less than X₁ into a single-crystal pulling furnace during growth of a silicon single-crystal by the CZ process in a hydrogen-containing inert atmosphere,
wherein the hydrogen gas concentration X₁ is defined as, in a triangular diagram of a ternary system of hydrogen gas, oxygen gas and inert gas having vertices A, B and C where K₁ is a mixed gas dilution limit for detonation and D is a composition of air on a side BC representing a volumetric ratio of the oxygen gas and the inert gas, hydrogen gas concentration at a point S₁ where a straight line from D toward K₁ intersects a side CA representing a volumetric ratio of the inert gas and the hydrogen gas.

2. A method for supplying hydrogen gas in silicon single-crystal growth according to claim 1, wherein letting L₁ to L₁′ be a detonation range on side AB representing a volumetric ratio of the hydrogen gas and the oxygen gas and letting M₁ to M₁′ be a detonation range on a straight line DA which connects the air composition D on side BC representing the volumetric ratio of the oxygen gas and inert gas with the vertex A, the mixed gas dilution limit for detonation K₁ is a point where straight line L₁M₁ and straight line L₁′M₁′ intersect.

3. A method for supplying hydrogen gas in silicon single-crystal growth according to claim 1, wherein the hydrogen gas is fed at a hydrogen gas concentration of X₂ or more, and the hydrogen gas concentration X₂ is defined as, in the triangular diagram of the ternary system of hydrogen gas, oxygen gas and inert gas having vertices A, B and C where K₂ is a mixed gas dilution limit for combustion and D is the air composition on side BC representing the volumetric ratio of the oxygen gas and the inert gas, hydrogen gas concentration at a point S₂ where a straight line from D toward K₂ intersects side CA representing the volumetric ratio of the inert gas and the hydrogen gas.

4. A method for supplying hydrogen gas in silicon single-crystal growth according to claim 3, wherein letting L₂ to L₂′ be a combustion range on side AB representing the volumetric ratio of the hydrogen gas and the oxygen gas and letting M₂ to M₂′ be a combustion range on a straight line DA which connects the air composition D on side BC representing the volumetric ratio of the oxygen gas and inert gas with the vertex A, the mixed gas dilution limit for combustion K₂ is a point where straight line L₂M₂ and straight line L₂′M₂′ intersect.

5. A method for supplying hydrogen gas in silicon single-crystal growth according to claim 3, wherein the method comprises sensing a rise in the oxygen concentration in ambient gases in the furnace during a single-crystal pulling operation, and issuing an alarm until the oxygen concentration reaches an oxygen gas concentration O₀, and the oxygen gas concentration O₀ is defined as oxygen gas concentration at a point S₀ where a straight line DS that connects the air composition D on the side BC representing the volumetric ratio of the oxygen gas and the inert gas with an operation point S on the side CA representing the volumetric ratio of the inert gas and the hydrogen gas intersects a straight line L₂′K₂ representing the upper limit of a combustion region.

6. A method for supplying hydrogen gas in silicon single-crystal growth according to claim 5, wherein the alarm is set off when the oxygen gas concentration in the ambient gases reaches a value in a range from 0.1-fold to 0.25-fold of the oxygen gas concentration O₀.

7. A method for supplying hydrogen gas in silicon single-crystal growth according to claim 1, wherein the hydrogen gas is fed at a hydrogen gas concentration of less than X₂, and the hydrogen gas concentration X₂ is defined as, in the triangular diagram of the ternary system of hydrogen gas, oxygen gas and inert gas having vertices A, B and C where K₂ is a mixed gas dilution limit for combustion and D is the air composition on side BC representing the volumetric ratio of the oxygen gas and the inert gas, hydrogen gas concentration at a point S₂ where a straight line from D toward K₂ intersects side CA representing the volumetric ratio of the inert gas and the hydrogen gas.

8. A method for supplying hydrogen gas in silicon single-crystal growth according to claim 7 wherein, letting L₂ to L₂′ be a combustion range on side AB representing the volumetric ratio of the hydrogen gas and the oxygen gas and letting M₂ to M₂′ be a combustion range on a straight line DA which connects the air composition D on side BC representing the volumetric ratio of the oxygen gas and inert gas with the vertex A, the mixed gas dilution limit for combustion K₂ is a point at which straight line L₂M₂ and straight line L₂′M₂′ intersect.

9. A method for manufacturing a silicon single-crystal, comprising:
a step of growing a silicon single-crystal by the CZ method in an hydrogen-containing inert atmosphere; and
a step of feeding hydrogen gas into a single-crystal pulling furnace at a hydrogen gas concentration of less than X₁,
wherein the hydrogen gas concentration X₁ is defined as, in a triangular diagram of a ternary system of hydrogen gas, oxygen gas and inert gas having vertices A, B and C where K₁ is a mixed gas dilution limit for detonation and D is a composition of air on side BC representing a volumetric ratio of the oxygen gas and the inert gas, hydrogen gas concentration at a point S₁ where a straight line from D toward K₁ intersects side CA representing a volumetric ratio of the inert gas and the hydrogen gas.
